(19) United States
(12) Patent Application Publication
(10) Pub. No.: US 2025/0220887 A1
(43) Pub. Date: Jul. 3, 2025

(54) SEMICONDUCTOR DEVICE AND METHOD FOR FABRICATING THE SAME

(71) Applicant: SK hynix Inc., Gyeonggi-do (KR)

(72) Inventor: Sung Hwan HWANG, Gyeonggi-do (KR)

(21) Appl. No.: 18/747,444

(22) Filed: Jun. 19, 2024

(30) Foreign Application Priority Data
Dec. 27, 2023 (KR) 10-2023-0193016

(51) Int. Cl. H10B 12/00

(52) U.S. Cl. CPC H10B 12/34; H10B 12/053

(57) ABSTRACT

A semiconductor device includes a plurality of active regions in a substrate; a gate trench formed in at least one of the plurality of the active regions, the gate trench including a first sidewall, a second sidewall opposite to the first sidewall, and a bottom sidewall; a growth promotion region formed on the first sidewall of the trench; a first gate dielectric layer formed on the first sidewall of the trench to contact the growth promotion region; a second gate dielectric layer formed on the second sidewall of the trench to be thinner than the first gate dielectric layer; and a gate electrode partially filling the trench over the first and second gate dielectric layers.

### CROSS-REFERENCE TO RELATED APPLICATIONS

The present application claims priority under 35 U.S.C 119 (a) to Korean Patent Application No. 10-2023-0193016, filed on Dec. 27, 2023, which is incorporated herein by reference in its entirety.

### BACKGROUND

### 1. Field

Various embodiments of the present disclosure relate generally to a semiconductor device, and more particularly, to a semiconductor device including a buried gate structure, and a method for fabricating the semiconductor device.

### 2. Description of the Related Art

Metal gate electrodes are used to ensure high performance of transistors. In particular, buried gate transistors are specialized type transistors which bury the gate electrode within a trench in the semiconductor substrate. Buried gate transistors require to control a threshold voltage for a high-performance operation. Also, Gate Induced Drain Leakage (GIDL) characteristics have a significant influence on the performance of the buried gate-type transistors.

### SUMMARY

Embodiments of the present disclosure are directed to a semiconductor device including a buried gate structure with improved reliability, and a method for fabricating the semiconductor device.

In accordance with an embodiment of the present disclosure, a semiconductor device includes a plurality of active regions in a substrate; a gate trench formed in at least one of the plurality of the active regions, the gate trench including a first sidewall, a second sidewall opposite to the first sidewall, and a bottom sidewall; a growth promotion region formed on the first sidewall of the trench; a first gate dielectric layer formed on the first sidewall of the trench to contact the growth promotion region; a second gate dielectric layer formed on the second sidewall of the trench to be thinner than the first gate dielectric layer; and a gate electrode partially filling the trench over the first and second gate dielectric layers.

In accordance with an embodiment of the present disclosure, a semiconductor device includes a substrate; an isolation layer defining an active region including a first node and a second node in the substrate; a gate trench formed between the first node and the second node and including a first sidewall and a second sidewall; a growth promotion region formed on the first sidewall of the trench; a first gate dielectric layer formed on the first sidewall of the trench to contact the growth promotion region; a second gate dielectric layer formed on the second sidewall of the trench to be thinner than the first gate dielectric layer; a gate electrode partially filling the trench over the first and second gate dielectric layers; and a potential barrier region formed in the second node below the second sidewall of the gate trench.

In accordance with an embodiment of the present disclosure, a method for fabricating a semiconductor device includes forming a plurality of active regions in a substrate; forming a gate trench including a first sidewall and a second sidewall facing the first sidewall in each of the active regions; doping the first sidewall of the trench with a growth promotion species; forming a first gate dielectric layer and a second gate dielectric layer on the first sidewall and the second sidewall of the gate trench, respectively; and forming a gate electrode partially filling the trench over the first and second gate dielectric layers. The growth promotion species includes an oxidation promotion species to increase a growth rate of the first gate dielectric layer. The growth promotion species includes oxygen, fluorine, or a combination thereof. The doping of the first sidewall of the trench with the growth promotion species includes a tilt implantation process. In forming the gate trench, each of the active regions includes a first node and a second node obtained by being divided by the gate trench. The method further comprising forming a first doped region in first nodes of the active regions; forming a second doped region in second nodes of the active regions; and forming a potential barrier region below one doped region among the first doped region and the second doped region. The potential barrier region includes a P-type dopant. The method further comprising forming an isolation layer defining the active regions in the substrate, wherein one gate electrode is disposed in each active region of the active regions.

In accordance with an embodiment of the present disclosure, a semiconductor device includes a substrate; an isolation layer defining an active region including a first node and a second node in the substrate; a gate trench formed between the first node and the second node and including a first sidewall and a second sidewall; a first gate dielectric layer formed on the first sidewall of the gate trench; a second gate dielectric layer formed on the second sidewall of the gate trench to be thinner than the first gate dielectric layer; a gate electrode partially filling the gate trench over the first and second gate dielectric layers; and a highly doped region formed in the second node below the second sidewall of the gate trench.

In accordance with an embodiment of the present disclosure, a semiconductor device includes a substrate; an isolation layer defining an active region including a first node and a second node in the substrate; a gate trench formed between the first node and the second node and including a first sidewall and a second sidewall; a first gate dielectric layer formed on the first sidewall of the gate trench; a second gate dielectric layer formed on the second sidewall of the trench to be thinner than the first gate dielectric layer; a gate electrode partially filling the gate trench over the first and second gate dielectric layers; and a highly doped region formed in the first node below the first sidewall of the gate trench.

In accordance with an embodiment of the present disclosure, a semiconductor device includes bit lines extending in a first direction, gate electrodes extending in a second direction crossing the first direction, active regions disposed at intersections between the gate electrodes and the bit lines and including first nodes coupled to the bit lines and second nodes confronting the first nodes; data storage elements respectively coupled to the second nodes of the active regions; first gate dielectric layers formed between the second nodes and the gate electrodes; and second gate dielectric layers formed between the first nodes and the gate electrodes to be thinner than the first gate dielectric layers, wherein the first nodes, the gate electrodes, and the second nodes are unidirectional, and one gate electrode may be disposed in each active region of the active regions.

These and other features and advantages of the embodiments of the present disclosure will become apparent to those of ordinary skill in the art from the following detailed description in conjunction with the following drawings.

### BRIEF DESCRIPTION OF THE DRAWINGS

FIG. 1A is a plan view illustrating a semiconductor device in accordance with an embodiment of the present disclosure.

FIG. 1B is a cross-sectional view taken along a line A-A′ shown in FIG. 1A.

FIG. 1C is a cross-sectional view taken along a line B-B′ shown in FIG. 1A.

FIG. 1D illustrates a data storage element shown in FIG. 1B.

FIGS. 2A to 7A are plan views illustrating a method for fabricating a semiconductor device in accordance with embodiment of the present disclosure.

FIGS. 2B to 7B are cross-sectional views taken along a line A-A′ shown in FIGS. 2A to 7A.

FIG. 8A is a plan view illustrating a semiconductor device in accordance with an embodiment of the present disclosure.

FIG. 8B is a cross-sectional view taken along a line A-A′ shown in FIG. 8A.

FIG. 8C is a cross-sectional view taken along a line C-C′ shown in FIG. 8A.

FIG. 9A illustrates a method for forming a highly doped region shown in FIG. 8B.

FIG. 9B is another embodiment of a method for forming the highly doped region shown in FIG. 8B.

FIGS. 10A and 10B are cross-sectional views taken along a line A-A′ and a line C-C′ shown in FIG. 8A in accordance with an embodiment of the present disclosure.

FIGS. 11 to 14 are cross-sectional views illustrating semiconductor devices in accordance with other embodiments of the present disclosure.

FIG. 15 is a plan view illustrating a semiconductor device in accordance with an embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure. The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

In the following embodiments of the present disclosure, a buried gate structure may be disposed in a trench. The buried gate structure may include a stack of a gate dielectric layer, a gate electrode, and a capping layer. The gate dielectric layer may cover the surface of the trench, and the gate electrode may partially fill the trench over the gate dielectric layer, and the capping layer may fill the other portion of the trench over the gate electrode. Therefore, the gate electrode may be referred to as a ‘buried gate electrode.’

The gate electrode may include a single gate or a dual gate. The single gate may refer to a gate formed of polysilicon alone or a metal-based material alone. The single gate may include a polysilicon single gate or a metal single gate. The dual gate may refer to a bi-layer stack of different gate materials. The dual gate may include a homogeneous metal dual gate which is formed of a stack of the same metal, a heterogeneous metal dual gate which is formed of a stack of different metals, or a heterogeneous material dual gate which is formed of a stack of a metal and polysilicon.

The gate electrode may include a barrier layer and a low-resistance material. The barrier layer may serve to block the dopants diffused from a low-resistance material or to prevent mutual diffusion and reaction between different materials. The low-resistance materials may serve to reduce the sheet resistance of the gate electrode.

The gate electrode may include a material with an engineered work function. The work function engineering may refer to a material or a method that may adjust a work function to have a decreased work function (i.e., a low work function) or an increased work function (i.e., a high work function).

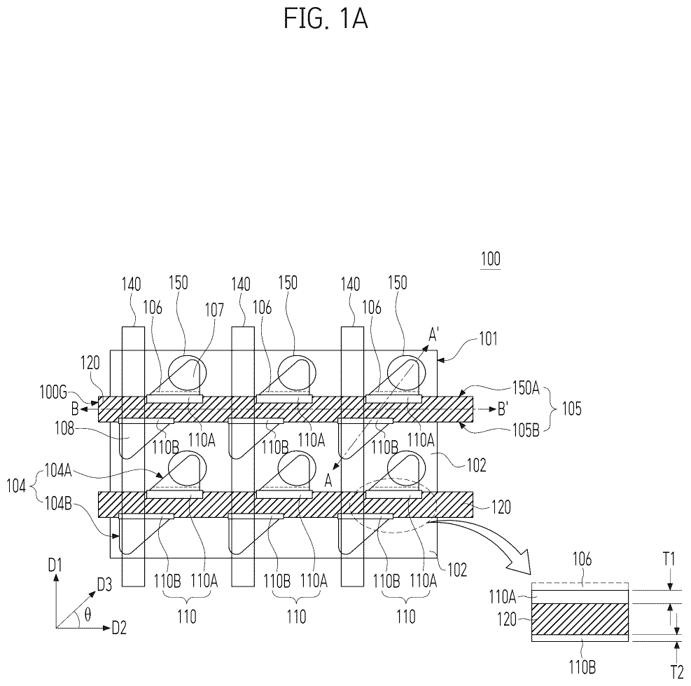

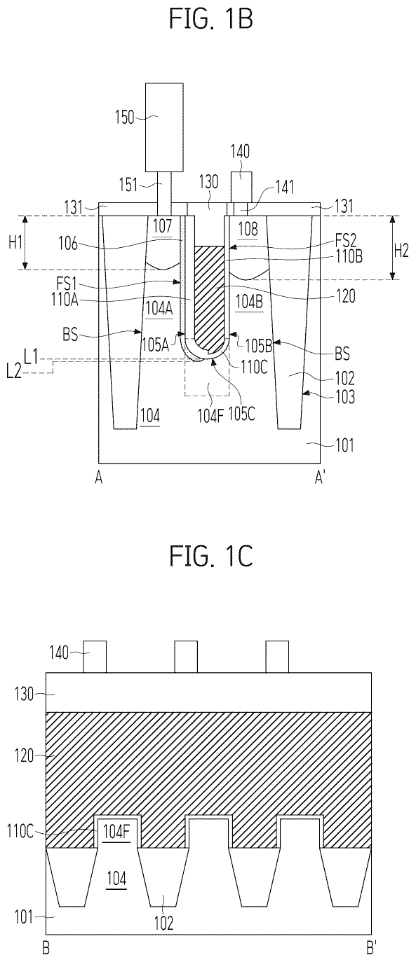

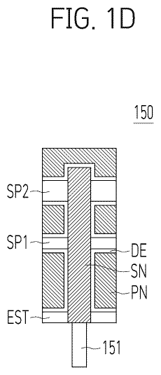

FIG. 1A is a plan view illustrating a semiconductor device in accordance with an embodiment of the present disclosure. FIG. 1B is a cross-sectional view taken along a line A-A′ shown in FIG. 1A. FIG. 1C is a cross-sectional view taken along a line B-B′ shown in FIG. 1A. FIG. 1D illustrates a data storage element 150 shown in FIG. 1B.

Referring to FIGS. 1A to 1D, the semiconductor device 100 may include a substrate 101, a plurality of buried gate structures 100G, a plurality of bit lines 140, and a plurality of data storage elements 150. The semiconductor device 100 may include a plurality of memory cells. For example, the semiconductor device 100 may include a portion of a Dynamic Random Access Memory (DRAM). Each memory cell may include one buried gate structure 100G, one bit line 140, and one data storage element 150. The bit lines 140 may extend in a first direction D1, and the buried gate structures 100G may extend in a second direction D2. The first direction D1 and the second direction D2 may be orthogonal to each other.

The substrate 101 may include a material appropriate for semiconductor processing. The substrate 101 may include a semiconductor substrate. The substrate 101 may include a material containing silicon. The substrate 101 may include, for example, silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include other semiconductor materials, such as germanium. The substrate 101 may include a group III/V semiconductor substrate, for example, a compound semiconductor substrate, such as gallium arsenide (GaAs). The substrate 101 may include a Silicon-On-Insulator (SOI) substrate.

An isolation layer 102 and a plurality of active regions 104 may be formed over the substrate 101. The plurality of active regions 104 may be defined by the isolation layer 102. The isolation layer 102 may include a Shallow Trench Isolation (STI) region that is formed by a trench etching process. The isolation layer 102 may be formed by filling a shallow trench, for example, an isolation trench 103, with a dielectric material, such as, for example, silicon oxide, silicon nitride, or a combination thereof.

A gate trench 105 may be formed in the substrate 101. From a top view perspective shown in FIG. 1A, the gate trench 105 may have a line shape extending in the second direction D2. The gate trench 105 may be deep and narrow. The gate trench 105 may extend deep in the D3 direction. The gate trench 105 may have a narrow width in the D1 direction. The width may vary depending on the application. The gate trench 105 may have a line shape crossing the active regions 104 and the isolation layer 102. The gate trench 105 may have a shallower depth than the isolation trench 103. According to an embodiment of the present disclosure, the gate trench 105 may include a space in which the buried gate structure 100G is to be formed, and the gate trench 105 may also be referred to as a ‘buried gate trench.’ The gate trench 105 may include a first sidewall 105A, a second sidewall 105B, and a bottom surface 105C. The bottom surface 105C of the gate trench 105 may be disposed at a first level L1 (also referred to as first depth).

The active regions 104 may be formed of strips and may be arranged in the form of an array. The array of active regions 104 may include a column array and a row array. The column array of active regions 104 may include active regions 104 that are arranged in the first direction D1. The row array of active regions 104 may include active regions 104 that are arranged in the second direction D2. The longitudinal direction of the active regions 104, that is, a third direction D3, may be non-orthogonal to the first direction D1 and the second direction D2, forming an intersection angle θ. The intersection angle θ between the second direction D2 and the third direction D3 of the active region 104 may range from approximately 10° to 80°, but the embodiments of the present disclosure may not be limited thereto. The range of the intersection angle θ may be affected by parameters, such as the area of the active region 104, the line width of the bit line 140, and the line width of the buried gate structure 100G. From a top view perspective, the cross-section of each active region 104 may include a parallelogram, for example a parallelogram having rounded edges.

The active regions 104 may be arranged in a unidirection of the third direction D3.

Each gate trench 105 may divide each of the active regions 104 arranged in the second direction D2 into a first node 104A and a second node 104B. The first and second nodes 104A and 104B may be referred to as first and second contact regions, respectively. The first and second nodes 104A and 104B may be referred to as first and second active nodes, respectively. The first node 104A and the second node 104B may be asymmetrical to each other in the third direction D3. The first node 104A and the second node 104B may respectively include flat sidewalls FS1 and FS2 and bended sidewalls BS. The flat sidewalls FS1 and FS2 of the first node 104A and the second node 104B may be exposed by the gate trench 105. The bended sidewalls BS of the first node 104A and the second node 104B may be covered by the isolation layer 102. The first sidewall 105A and the second sidewall 105B of the gate trench 105 may be provided by the flat sidewalls FS1 and FS2 of the first and second nodes 104A and 104B and the isolation layer 102. Accordingly, the first sidewall 105A of the gate trench 105 may include the flat sidewall FS1 of the first node 104A, and the second sidewall 105B of the gate trench 105 may include the flat sidewall FS2 of the second node 104B. The flat sidewalls FS1 and FS2 and the bended sidewall BS may be referred to as a sidewall facet. According to an embodiment of the present disclosure, the cross-sections of the first node 104A and the second node 104B may have a rectangular shape, a square shape, a circular shape, an elliptical shape, or a polygonal shape. When the cross-sections of the first node 104A and the second node 104B are polygons, they may have at least four sidewall facets.

A first doped region 107 and a second doped region 108 may be formed in each active region 104. The first doped region 107 may be formed in the first node 104A, and the second doped region 108 may be formed in the second node 104B. The first doped region 107 and the second doped region 108 may be regions that are doped with a conductive dopant. For example, the conductive dopant may include phosphorus (P), arsenic (As), antimony (Sb), or boron (B). The first doped region 107 and the second doped region 108 may be doped with a dopant of the same conductivity type. The first doped region 107 and the second doped region 108 may be disposed in the active regions 104 on both sides of the gate trench 105. The bottom surfaces of the first doped region 107 and the second doped region 108 may be disposed at a predetermined depth from the top surface of the active region 104. The first doped region 107 and the second doped region 108 may contact the sidewalls of the gate trench 105. The bottom surfaces of the first doped region 107 and the second doped region 108 may be higher than the bottom surface 105C of the gate trench 105. The first doped region 107 may be referred to as a ‘first source/drain region’, and the second doped region 108 may be referred to as a ‘second source/drain region’. A channel may be defined between the first doped region 107 and the second doped region 108 by the buried gate structure 100G. The channel may be defined along the profile of the gate trench 105. The depth H1 of the first doped region 107 may be smaller than the depth H2 of the second doped region 108. Since the first doped region 107 and the second doped region 108 have different depths, an asymmetric junction structure may be formed.

A growth promotion region 106 may be formed in the active region 104. The growth promotion region 106 may directly contact the first doped region 107. The growth promotion region 106 may be formed by a tilt implantation process. The growth promotion region 106 may include a growth promotion species. The growth promotion region 106 may be formed by implanting growth promotion species via a tilt implantation process to a desired depth and dosage by controlling the amount of the growth promotion species per area, their acceleration energy and the tilt angle. The growth promotion species are selected to promote the growth rate of an oxide during a subsequent oxidation process. The growth promotion species may be referred to also as oxidation promotion species. The growth promotion species may include, for example, oxygen, fluorine, or a combination thereof. The growth promotion region 106 may be formed on the flat sidewall FS1 of the first node 104A. The growth promotion region 106 may not be formed on the flat sidewall FS2 of the second node 104B. The bottom surface of the growth promotion region 106 may be disposed at a second level L2. The second level L2 may be disposed at a lower level than the first level L1. The bottom surface of the growth promotion region 106 may be disposed at a lower level than the bottom surface 105C of the gate trench 105. The growth promotion region 106 may cover a small section of the bottom wall 105C of the gate trench 105. The growth promotion region 106 may have a uniform width except for a lowermost end region thereof which may have a reducing tapering width towards an end thereof.

The active region 104 may include a fin region 104F. The fin region 104F may be disposed below the gate trench 105. The fin region 104F may be formed, as a portion of the isolation layer 102 below the gate trench 105 is recessed. The sidewall of the fin region 104F may be exposed by the recessed isolation layer 102. The fin region 104F may include a part where a portion of a channel is formed. The fin region 104F may be called a saddle fin. The fin region 104F may increase the channel width and improve electrical characteristics. According to an embodiment of the present disclosure, the fin region 104F may be omitted. A portion of the growth promotion region 106 may extend into the fin region 104F. The bottom surface of the growth promotion region 106 may extend into the top surface of the fin region 104F.

According to an embodiment of the present disclosure, the active region 104 and the fin region 104F may include an oxide semiconductor material, such as InGaZnO (IGZO). In this case, the first doped region 107 and the second doped region 108 may also include an oxide semiconductor material, such as IGZO. The active region 104 and the fin region 104F may be IGZO, and the first doped region 107 and the second doped region 108 may be an oxide semiconductor material whose resistance is lower than the resistance of IGZO.

From a top view perspective shown in FIG. 1A, the buried gate structure 100G may extend in the first direction D1. The buried gate structure 100G may include a gate dielectric layer 110 covering the bottom and sidewalls of the gate trench 105, a gate electrode 120 partially filling the gate trench 105 over the gate dielectric layer 110, and a capping layer 130 over the gate electrode 120.

The gate dielectric layer 110 may include first gate dielectric layers 110A and second gate dielectric layers 110B. The first gate dielectric layers 110A may be formed on the flat sidewalls FS1 of the first nodes 104A. The second gate dielectric layers 110B may be formed on the flat sidewalls FS2 of the second nodes 104B. The thickness T1 of the first gate dielectric layers 110A may be greater than the thickness T2 of the second gate dielectric layers 110B. The first gate dielectric layers 110A may be formed over the growth promotion regions 106.

During the oxidation process for forming the gate dielectric layer 110, the growth rates of the first gate dielectric layers 110A and the second gate dielectric layers 110B may be different from each other.

The first gate dielectric layers 110A may grow faster than the second gate dielectric layers 110B. The first gate dielectric layers 110A may grow faster on the flat sidewalls FS1 of the first nodes 104A than the second gate dielectric layers 110B on the surfaces of the flat sidewalls FS2 of the second nodes 104B because of the growth promotion regions 106. the oxygen and/or fluorine in the growth promotion regions 106 serve to promote the growth rate of the first gate dielectric layers 110A.

The first gate dielectric layer 110A may include, for example, silicon oxide, and the growth promotion region 106 may include an oxygen-containing silicon layer. The first gate dielectric layer 110A may include, for example, silicon oxide, and the growth promotion region 106 may include a fluorine-containing silicon layer. The first gate dielectric layer 110A may include, for example, silicon oxide, and the growth promotion region 106 may include a silicon layer containing oxygen and fluorine.

According to an embodiment of the present disclosure, the growth promotion region 106 may be partially converted or fully converted to form the first gate dielectric layer 110A. For example, the growth promotion region 106 may be partially oxidized or fully oxidized to become a portion of the first gate dielectric layer 110A. The first gate dielectric layer 110A may be fluorine-containing silicon oxide or may have a dual structure of undoped silicon oxide and fluorine-containing silicon oxide. Fluorine-containing silicon oxide as this term is used here means a silicon oxide doped with fluorine.

As described above, the first gate dielectric layers 110A and the second gate dielectric layers 110B may have different thicknesses, and accordingly, the gate dielectric layer 110 may include an asymmetric structure. A third gate dielectric layer 110C may also grow on the bottom surface 105C of the gate trench 105. The thickness of a portion of the third gate dielectric layer 110C may be the same as the thickness of the second gate dielectric layer 110B. The thickness of the first gate dielectric layer 110A may be thicker than a portion of the third gate dielectric layer 110C. The third gate dielectric layer 110C may have a variable thickness. For example, it may include a first portion having the same thickness as that of the second gate dielectric layer 110B, and a second portion having the same thickness as that of the first gate dielectric layer 110A. Since the growth promotion region 106 extends to a portion of the surface of the fin region 104F, the second portion of the third gate dielectric layer 110C may be formed partially thick on the surface of the fin region 104F.

According to an embodiment of the present disclosure, the gate dielectric layer 110 may further include an additional gate dielectric layer. The additional gate dielectric layer may be formed over the first and second gate dielectric layers 110A and 110B. The additional gate dielectric layer may be formed by a deposition method, such as Chemical Vapor Deposition (CVD) or Atomic Layer Deposition (ALD). The additional gate dielectric layer formed by a deposition method may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to an embodiment of the present disclosure, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may optionally be used.

According to an embodiment of the present disclosure, the gate dielectric layer 110 may include a stack of silicon oxide and a high-k material. Silicon oxide may be the first and second gate dielectric layers 110A and 110B, and the high-k material may be an additional gate dielectric layer. The high-k material may include materials having a higher areal density of oxygen atoms than that of silicon oxide. According to an embodiment of the present disclosure, the high-k material may include a material with a lower areal density of oxygen atoms than that of silicon oxide. For example, the stack of silicon oxide and the high-k material may include a silicon oxide/lanthanum oxide (SiO₂/La₂O₃) stack, and the lanthanum oxide may horizontally overlap with the first and second doped regions 107 and 108.

The gate electrode 120 may include a buried gate electrode that partially fills the gate trench 105. The gate electrode 120 may be disposed at a lower level than the top surface of the active region 104, that is, the first and second doped regions 107 and 108. The gate electrode 120 may include a semiconductor material, a metal-based material, or a combination thereof. The gate electrode 120 may include a metal, a metal nitride, or a combination thereof. The gate electrode 120 may include polysilicon, tantalum nitride (TaN), titanium nitride (TiN), tungsten (W), tungsten nitride (WN), molybdenum (Mo), ruthenium (Ru), or a combination thereof. The gate electrode 120 may be formed of titanium nitride alone. According to an embodiment of the present disclosure, the gate electrode 120 may have a high work function. For example, the high work function may refer to a work function that is higher than the mid-gap work function of silicon. A low work function may refer to a work function which is lower than the mid-gap work function of silicon. The high work function may have a work function which is higher than approximately 4.5 eV, and the low work function may have a work function which is lower than approximately 4.5 eV. The gate electrode 120 may include P-type polysilicon or nitrogen-rich titanium nitride (nitrogen-rich TiN).

According to an embodiment of the present disclosure, the gate electrode 120 may have an increased high work function. The gate electrode 120 may include a metal silicon nitride. The metal silicon nitride may be obtained by doping a metal nitride with silicon. The gate electrode 120 may include a metal silicon nitride with a controlled silicon content. For example, the gate electrode 120 may include tantalum silicon nitride (TaSiN) or titanium silicon nitride (TiSiN). Titanium nitride may have a high work function, and in order to further increase the work function of titanium nitride, titanium nitride may contain silicon. The content of silicon may be adjusted to increase the high work function of the titanium silicon nitride. According to an embodiment of the present disclosure, the gate electrode 120 may include titanium aluminum nitride (TiAlN).

The capping layer 130 may serve to protect the gate electrode 120. The capping layer 130 may fill the upper portion of the gate trench 105 over the gate electrode 120. The top surface of the capping layer 130 may be disposed at the same level as the top surfaces of the first and second doped regions 107 and 108. The capping layer 130 may include, for example, silicon oxide, silicon nitride, silicon carbon oxide, fluorine-containing silicon oxide, or a combination thereof.

The bit line 140 may be electrically connected to the second doped region 108. For example, the bit line 140 may be coupled to the second doped region 108 through first contact node 141. The data storage element 150 may be electrically connected to the first doped region 107. For example, the data storage element 150 may be coupled to the first doped region 107 through second contact node 151. The first contact node 141 may be referred to also as a bit line contact plug, and the second contact node 151 may be referred to also as a storage contact plug.

The first and second contact nodes 141 and 151 may include a semiconductor material, a doped semiconductor material, a metal-based material, a metal nitride-based material, a conductive metal oxide, or a combination thereof. For example, the first contact node 141 may include doped polysilicon, and the second contact node 151 may include a stacked structure of polysilicon, titanium nitride, and tungsten.

The bit line 140 may include a semiconductor material, a doped semiconductor material, a metal-based material, a metal nitride-based material, a conductive metal oxide, or a combination thereof. For example, the bit line 140 may include a stacked structure of titanium nitride and tungsten.

The data storage element 150 may include a memory element, such as a capacitor.

Referring to FIG. 1D, the data storage element 150 may include a first electrode SN, a second electrode PN over the first electrode SN, and a dielectric layer DE between the first electrode SN and the second electrode PN. The first electrode SN may have a pillar shape. According to an embodiment of the present disclosure, the first electrode SN may have a cylindrical shape, a plate shape, or a pylinder shape. The pylinder shape may refer to a structure in which a pillar shape and a cylindrical shape are merged.

The outer wall of the first electrode SN of the data storage element 150 may be supported by multi-level supporters SP1 and SP2. The multi-layer level supporters SP1 and SP2 may include, for example, silicon nitride, silicon carbon nitride, or a combination thereof as a dielectric material. According to an embodiment of the present disclosure, the multi-level supporters may include three or more supporters. The bottom portion of the first electrode SN of the data storage element 150 may be supported by an etch stop layer EST. The etch stop layer EST may include, for example, silicon nitride, silicon carbon nitride, or a combination thereof. The bottom portion of the first electrode SN of the data storage element 150 may be coupled to the second contact node 151 through the etch stop layer EST.

The first electrode SN and the second electrode PN of the data storage element 150 may include a metal, a noble metal, a metal nitride, a conductive metal oxide, a conductive noble metal oxide, a metal carbide, a metal silicide, or a combination thereof. For example, the first electrode SN and the second electrode PN may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a combination thereof. The second electrode PN may include a combination of a metal-based material and a silicon-based material. For example, the second electrode PN may include a stack of titanium nitride/silicon germanium/tungsten nitride (TiN/SiGe/WN). In the titanium nitride/silicon germanium/tungsten nitride (TiN/SiGe/WN) stack, silicon germanium may include a gap-fill material filling the inside of the first electrode SN, and titanium nitride (TiN) may serve as the second electrode PN of the data storage element 150, and tungsten nitride may include a low-resistance material.

The dielectric layer DE may be referred to as a capacitor dielectric layer or a memory layer. The dielectric layer DE may include, for example, silicon oxide, silicon nitride, a high-k material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to an embodiment of the present disclosure, the dielectric layer DE may be formed of a composite layer including two or more layers of the aforementioned high-k materials.

The dielectric layer DE may be formed of zirconium (Zr)-based

oxide. The dielectric layer DE may have a stacked structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. The ZA stack and the ZAZ stack may be referred to as zirconium oxide (ZrO₂)-based layers. According to an embodiment of the present disclosure, the dielectric layer DE may be formed of hafnium (Hf)-based oxide. The dielectric layer DE may have a stacked structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. The HA stack and the HAH stack may be referred to as hafnium oxide (HfO₂)-based layers. In the ZA stack, ZAZ stack, HA stack, and HAH stack, aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap energy than the high-k material. The dielectric layer DE may include, for example, silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to an embodiment of the present disclosure, the dielectric layer DE may include a stacked structure in which a high-k material and a high-bandgap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HZAZH (HfO₂/ZrO₂/Al₂O₃/ZrO₂/HfO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above stacked structure, aluminum oxide (Al₂O₃) may be thinner than zirconium oxide (ZrO₂) and hafnium oxide (HfO₂).

According to an embodiment of the present disclosure, the dielectric layer DE may include a high-k material and a high bandgap material, and may have a laminated structure in which a plurality of high-k materials and a plurality of high bandgap materials are stacked, or a mixed structure in which a high-k material and a high bandgap material are intermixed.

According to an embodiment of the present disclosure, the dielectric layer DE may include a ferroelectric material, an anti-ferroelectric material, or a combination thereof. For example, the dielectric layer DE may include hafnium zirconium oxide (HfZrO).

According to an embodiment of the present disclosure, the dielectric layer DE may include a combination of a high-k material and a ferroelectric material, a combination of a high-k material and an anti-ferroelectric material, a high-k material, or a combination of a ferroelectric material and an anti-ferroelectric material.

According to an embodiment of the present disclosure, an interface control layer may be further formed between the first electrode SN and the dielectric layer DE to improve prevention of a leakage current. The interface control layer may include titanium oxide (TiO₂), tantalum oxide (Ta₂O₅), niobium oxide (Nb₂O₅), niobium oxynitride (NbON), niobium nitride (NbN), or a combination thereof. The interface control layer may also be formed between the second electrode PN and the dielectric layer DE.

According to an embodiment of the present disclosure, the data storage element 150 may include a thyristor, a phase change material, a magnetic tunnel junction (MTJ), or a variable resistance material.

Referring to FIGS. 1A to 1D, the semiconductor device 100 may include a plurality of memory cells, and the neighboring memory cells may be isolated from each other by the isolation layer 102. One memory cell may be formed over one active region 104. In each memory cell, one gate electrode 120 may be formed in one active region 104, and this may be referred to as a ‘memory cell of a One Gate-One Active Region (1G1A) structure.’ In a memory cell of the 1G1A structure, since the bit line 140 is coupled to one active region 104, the memory cell may be coupled to one bit line 140. The memory cell of the 1G1A structure may include one transistor-one capacitor (1T1C). As a comparative example, in a typical DRAM, two memory cells may be formed in one active region, and two gate electrodes may be formed in one active region, and two neighboring memory cells may share one bit line.

In the semiconductor device 100 including a memory cell of the 1G1A structure, the active regions 104 may be arranged in a unidirection of the third direction D3. The isolation layer 102, the second node 104B, the second gate dielectric layer 110B, the gate electrode 120, the first gate dielectric layer 110A, the first node 104A, and the isolation layer 102 may be arranged sequentially in the unidirection of the third direction D3.

The semiconductor device 100 including a memory cell of the 1G1A structure may include a gate dielectric layer 110 of an asymmetric structure. In particular, since the thickness of the first gate dielectric layer 110A is thicker than the thickness of the second gate dielectric layer 110B, leakage, such as Gate-Induced Drain Leakage (GIDL), may be suppressed, and since the leakage is suppressed, a refresh operation may be improved.

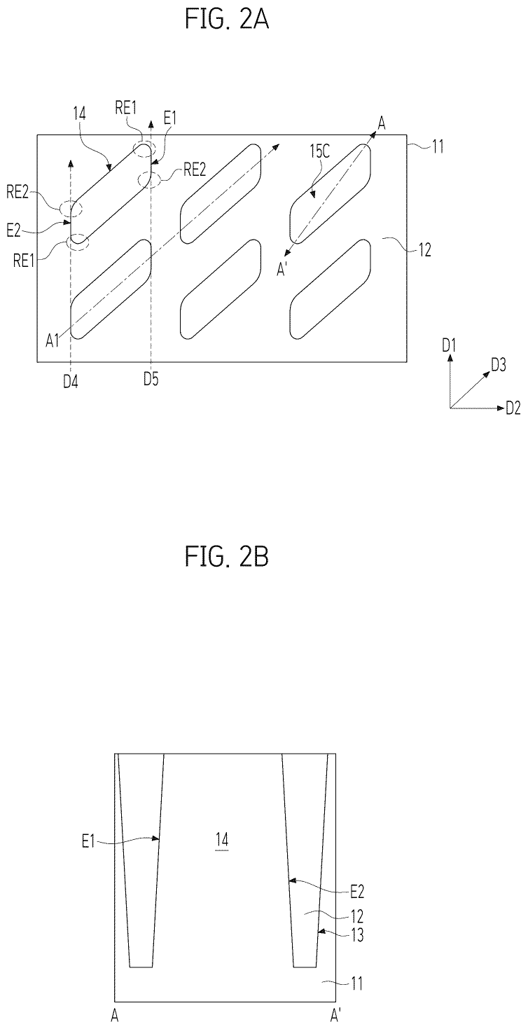

FIGS. 2A to 7A are plan views illustrating a method for fabricating a semiconductor device in accordance with an embodiment of the present disclosure. FIGS. 2B to 7B are cross-sectional views taken in a line A-A′ shown in FIGS. 2A to 7A.

Referring to FIGS. 2A and 2B, an isolation layer 12 and a plurality of active regions 14 may be formed over a substrate 11. The plurality of active regions 14 may be defined by the isolation layer 12. The substrate 11 may include a material suitable for semiconductor processing. The substrate 11 may include at least one among a conductive material, a dielectric material, and a semiconductive material. Diverse materials may be formed over the substrate 11. The substrate 11 may include a semiconductor substrate. The substrate 11 may include a material containing silicon. The substrate 11 may include, for example, silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 11 may also include other semiconductor materials, such as germanium. The substrate 11 may include a group-III/V semiconductor substrate, for example, a compound semiconductor substrate, such as gallium arsenide (GaAs). The substrate 11 may include a Silicon-On-Insulator (SOI) substrate.

The isolation layer 12 may be formed by a Shallow Trench Isolation (STI) process. For example, an isolation trench 13 may be formed by etching the substrate 11. Subsequently, the isolation trench 13 may be filled with a dielectric material, thereby forming the isolation layer 12. The isolation layer 12 may include, for example, silicon oxide, silicon nitride, or a combination thereof. Chemical vapor deposition (CVD) or another deposition process may be used to fill the isolation trench 13 with a dielectric material. A planarization process, such as chemical-mechanical polishing (CMP), may be additionally used.

Each of the active regions 14 may have an island shape. Each active region 14 may include a first end surface E1 and a second end surface E2 facing the first end surface E1. Each active region 14 may further include a plurality of rounded edges RE1 and RE2. The curvature of first round edges RE1 and the curvature of second round edges RE2 may be different from each other.

The active regions 14 may be regularly arranged in the first direction D1. The active regions 14 may be regularly arranged in the second direction D2. The active regions 14 may be regularly arranged in the third direction D3. The active regions 14 disposed adjacent to each other in the second direction D2 may be parallel in the third direction D3. The first end surfaces E1 of the active regions 14 disposed adjacent to each other in the first direction D1 may be arranged in a fourth direction D4, and the second end surfaces E2 of the active regions 14 disposed adjacent to each other in the first direction D1 may be arranged in a fifth direction D5. The fourth direction D4 and the fifth direction D5 may be directions parallel to the first direction D1. The first end surfaces E1 and the second end surfaces E2 of the active regions 14 may be arranged in the third direction D3, and thus the active regions 14 may be arranged in the third direction D3. The active regions 14 may be arranged in a unidirection A1 of the third direction D3.

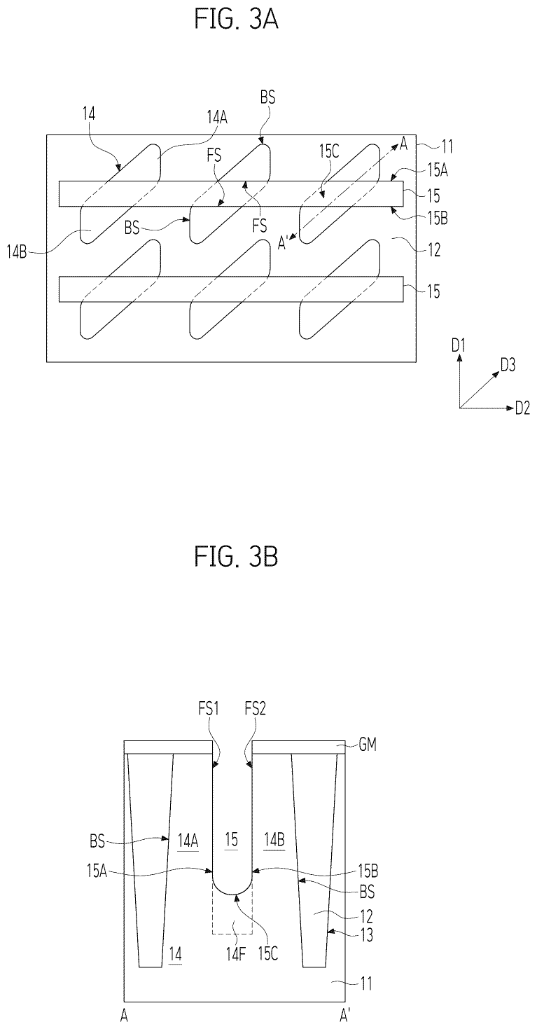

Referring to FIGS. 3A and 3B, a gate trench 15 may be formed in the substrate 11. The gate trench 15 may be formed in a line shape crossing the active regions 14 and the isolation layer 12. For example, the gate trench 15 may extend in the second direction D2.

The gate trench 15 may be formed by etching the substrate 11 with a hard mask layer GM used as an etch mask. The hard mask layer GM may be formed over the substrate 11 and may have a line-shaped opening for allowing the forming of the gate trench 15. The hard mask layer GM may be formed of a material having an etch selectivity with respect to the active region 14 and the isolation layer 12. The hard mask layer GM may include a silicon oxide, such as TEOS (Tetra-Ethyl-Ortho-Silicate). The gate trench 15 may be formed shallower than the isolation trench 13. The depth of the gate trench 15 may be less than the depth of the isolation trench 13 but should be sufficiently deep to increase the average cross-sectional area of the gate electrode to be formed subsequently. Accordingly, the resistance of the gate electrode may be decreased. The bottom edge of the gate trench 15 may be flat or may have a curvature.

Each active region 14 may be divided into two nodes 14A and 14B by the gate trench 15. For example, each active region 14 may be divided into a first node 14A and a second node 14B. The first node 14A and the second node 14B may be asymmetrical in a unidirection of the third direction D3. The first node 14A and the second node 14B may include flat sidewalls FS1 and FS2 and bended sidewalls BS, respectively (see FIG. 3A). The flat sidewalls FS1 and FS2 of the first node 14A and the second node 14B may be exposed by the gate trench 15. The bended sidewalls BS of the first node 14A and the second node 14B may be covered by the isolation layer 12. The flat sidewalls FS1 and FS2 and the bended sidewall BS may be referred to as a sidewall facet. According to an embodiment of the present disclosure, the cross-sections of the first node 14A and the second node 14B may have a rectangular shape, a square shape, a circular shape, an elliptical shape, or a polygonal shape. When the cross-sections of the first node 14A and the second node 14B are a polygonal shape, they may have at least four sidewall facets.

The gate trench 15 may include a first sidewall 15A, a second sidewall 15B, and a bottom surface 15C. The first and second sidewalls 15A and 15B of the gate trench 15 may be provided by the flat sidewalls FS1 and FS2 of the first and second nodes 14A and 14B and the isolation layer 12. Accordingly, the first sidewall 15A of the gate trench 15 may include the flat sidewall FS1 of the first node 14A, and the second sidewall 15B of the gate trench 15 may include the flat sidewall FS2 of the second node 14B.

After the gate trench 15 is formed, a fin region 14F may be formed subsequently. To form the fin region 14F, the isolation layer 12 below the gate trench 15 may be selectively recessed in the second direction D2.

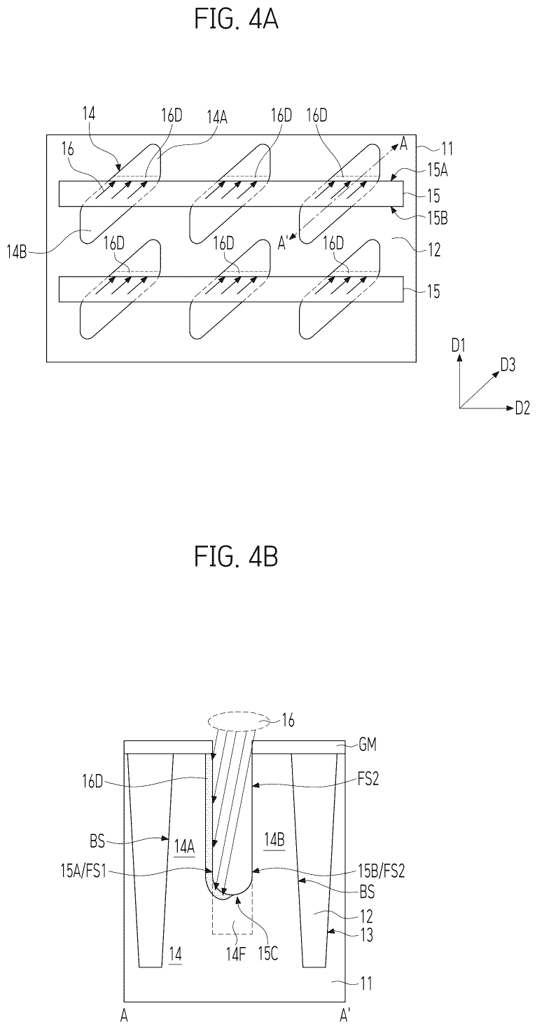

Referring to FIGS. 4A and 4B, a doping process 16 may be performed onto the first sidewall 15A of the gate trench 15. The doping process 16 may be performed onto the flat sidewall FS1 of the first node 14A. The doping process 16 may include a tilt implantation process.

In the tilt implantation process, a doping process may be performed at a tilt angle. By contrast, the doping process 16 is not performed on the flat sidewall FS2 of the second node 14B due to a shadow effect which may be caused by the tilt implantation process and the hard mask layer GM.

A growth promotion species, for example, an oxidation promotion species, may be doped by the doping process 16. The oxidation promotion species may include oxygen, fluorine, or a combination thereof. The oxidation promotion species may include a non-conductive species. For example, a dopant concentration of the growth promotion species may range from approximately 1.0×10¹² atoms/cm³ to approximately 1.0×10¹⁶ atoms/cm³.

A growth promotion region 16D may be formed on the flat sidewall FS1 of the first node 14A through the doping process 16. The growth promotion region 16D is not formed on the flat sidewall FS2 of the second node 14B. The growth promotion region 16D may extend to be formed on a portion of the surface of the fin region 14F. The bottom surface of the growth promotion region 16D may be disposed at a lower level than the bottom surface 15C of the gate trench 15.

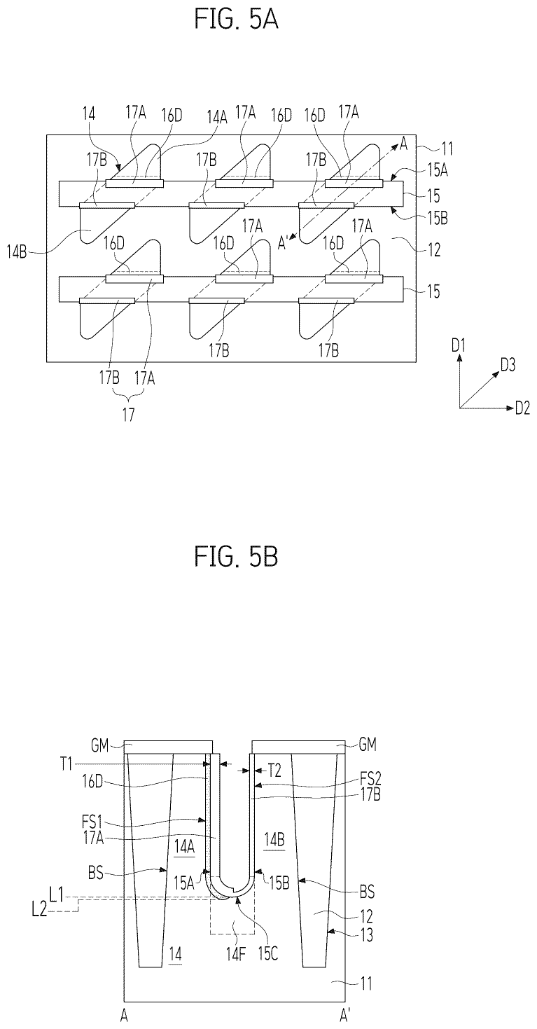

Referring to FIGS. 5A and 5B, a gate dielectric layer 17 may be formed on the first and second sidewalls 15A and 15B of the gate trench 15. Before the gate dielectric layer 17 is formed, etch damage on the surface of the gate trench 15 may be cured. For example, after a sacrificial oxide is formed through a thermal oxidation treatment, the sacrificial oxide may be removed. The gate dielectric layer 17 may be formed through a thermal oxidation process. The gate dielectric layer 17 may include, for example, silicon oxide.

The gate dielectric layer 17 may be selectively formed on the flat sidewalls FS1 of the first nodes 14A and the flat sidewalls FS2 of the second nodes 14B.

The gate dielectric layer 17 may include first gate dielectric layers 17A and second gate dielectric layers 17B. The first gate dielectric layers 17A may be formed on the flat sidewalls FS1 of the first nodes 14A. The second gate dielectric layers 17B may be selectively formed on the flat sidewalls FS2 of the second nodes 14B. The thickness T1 of the first gate dielectric layers 17A may be greater than the thickness T2 of the second gate dielectric layers 17B. The first gate dielectric layers 17A may be formed over the growth promotion regions 16D.

During the oxidation process for forming the gate dielectric layer 17, the growth rates of the first gate dielectric layers 17A and the second gate dielectric layers 17B may be different. For example, the first gate dielectric layers 17A may grow faster on the flat sidewalls FS1 of the first nodes 14A where the growth promotion regions 16D are formed than the second gate dielectric layers 17B on the surfaces of the flat sidewalls FS2 of the second nodes 14B. Oxygen and/or fluorine in the growth promotion regions 16D may serve to promote the growth rate of the first gate dielectric layers 17A.

The first and second gate dielectric layers 17A and 17B may include, for example, silicon oxide. The first gate dielectric layer 17A may include thick silicon oxide, and the second gate dielectric layer 17B may include thin silicon oxide. The first gate dielectric layer 17A may include, for example, silicon oxide, and the growth promotion region 16D may include an oxygen-containing silicon layer. The first gate dielectric layer 17A may include, for example, silicon oxide, and the growth promotion region 16D may include a fluorine-containing silicon layer. The first gate dielectric layer 17A may include, for example, silicon oxide, and the growth promotion region 16D may include a silicon layer containing oxygen and fluorine.

According to an embodiment of the present disclosure, the growth promotion region 16D may be partially converted or fully converted to form the first gate dielectric layer 17A. For example, the growth promotion region 16D may be partially oxidized or fully oxidized to become a portion of the first gate dielectric layer 17A. The first gate dielectric layer 17A may have a dual structure of undoped silicon oxide and fluorine-containing silicon oxide.

As described above, the first and second gate dielectric layers 17A and 17B may have different thicknesses, and accordingly, the gate dielectric layer 17 may include an asymmetric structure. A third gate dielectric layer (see a reference numeral ‘110C’ shown in FIG. 1B) may also grow on the bottom surface 15C of the gate trench 15. A portion of the third gate dielectric layer and the second gate dielectric layer 17B may have the same thickness. The thickness of the first gate dielectric layer 17A may be thicker than the thickness of a portion of the third gate dielectric layer. The third gate dielectric layer may have a variable thickness. For example, it may include a first portion having the same thickness as that of the second gate dielectric layer 17B, and a second portion having the same thickness as that of the first gate dielectric layer 17A. Since the growth promotion region 16D extends to a portion of the surface of the fin region 14F, the second portion of the third gate dielectric layer may be formed partially thick on the surface of the fin region 14F.

According to an embodiment of the present disclosure, the gate dielectric layer 17 may further include an additional gate dielectric layer. The additional gate dielectric layer may be formed over the first and second gate dielectric layers 17A and 17B. The additional gate dielectric layer may be formed by a deposition method, such as Chemical Vapor Deposition (CVD) or Atomic Layer Deposition (ALD). The additional gate dielectric layer formed by a deposition process may include a high-k material, an oxide, a nitride, an oxynitride, or a combination thereof. The high-k material may include hafnium containing materials. The hafnium-containing material may include hafnium oxide, hafnium silicon oxide, hafnium silicon oxynitride, or a combination thereof. According to an embodiment of the present disclosure, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may be optionally used.

According to an embodiment of the present disclosure, the gate dielectric layer 17 may include a stack of silicon oxide and a high-k material. The silicon oxide may be the first and second gate dielectric layers 17A and 17B, and the high-k material may be an additional gate dielectric layer. The high-k material may include materials having a higher areal density of oxygen atoms than that of silicon oxide.

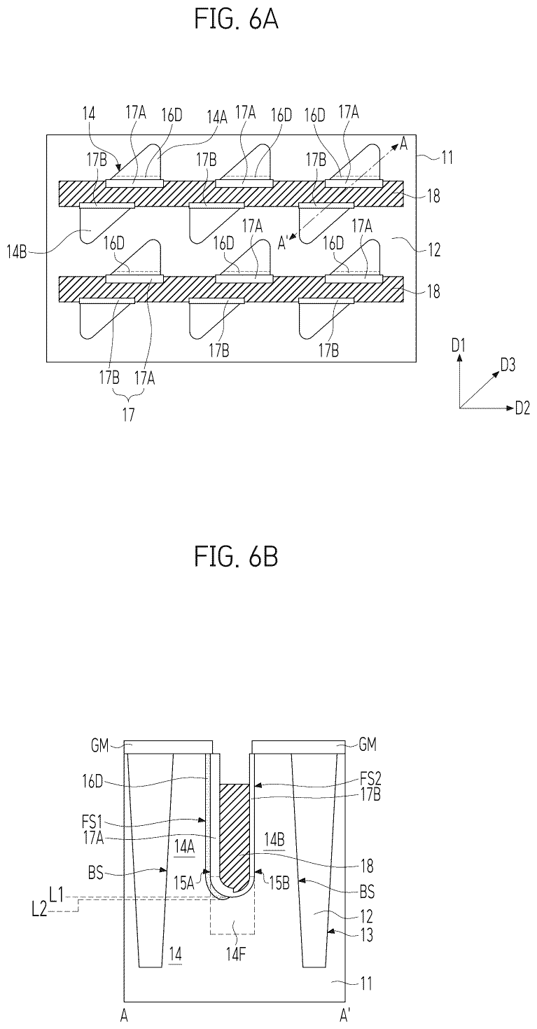

Referring to FIGS. 6A and 6B, a gate electrode 18 may be formed over the gate dielectric layer 17 to partially fill the gate trench 15.

The gate electrode 18 may be disposed at a lower level than the top surface of the active region 14. The gate electrode 18 may include a metal-based material. The gate electrode 18 may include a semiconductor material, a metal, a metal nitride, or a combination thereof. The gate electrode 18 may include polysilicon, tantalum nitride (TaN), titanium nitride (TiN), tungsten (W), tungsten nitride (WN), molybdenum (Mo), ruthenium (Ru), or a combination thereof. The gate electrode 18 may be formed of a stack of titanium nitride and tungsten, a stack of titanium nitride and polysilicon, or titanium nitride alone. According to an embodiment of the present disclosure, the gate electrode 18 may have a high work function. For example, the high work function may refer to a work function that is higher than the mid-gap work function of silicon. The low work function may refer to a work function that is lower than the mid-gap work function of silicon. The high work function may have a work function which is higher than approximately 4.5 eV, and the low work function may have a work function which is lower than approximately 4.5 eV. The gate electrode 18 may include P-type polysilicon or nitrogen-rich titanium nitride.

According to an embodiment of the present disclosure, the gate electrode 18 may have an increased high work function. The gate electrode 18 may include a metal silicon nitride. The metal silicon nitride may be obtained by doping a metal nitride with silicon. The gate electrode 18 may include a metal silicon nitride with a controlled silicon content. For example, the gate electrode 18 may include tantalum silicon nitride (TaSiN) or titanium silicon nitride (TiSiN). Titanium nitride may have a high work function. The titanium nitride may contain silicon in order to further increase the work function of titanium nitride.

The high work function of titanium silicon nitride may be increased by adjusting the content of silicon. According to an embodiment of the present disclosure, the gate electrode 18 may include titanium aluminum nitride (TiAlN).

Referring back to FIG. 6A, the first sidewall of the gate electrode 18 may contact the first gate dielectric layer 17A and the isolation layer 12, and the second sidewall of the gate electrode 18 may contact the second gate dielectric layer 17B and the isolation layer 12. The first and second sidewalls of the gate electrode 18 may include a plurality of flat surfaces and a plurality of recessed surfaces. For example, the flat surfaces refer to portions which contact the isolation layer 12, while the recessed surfaces refer to portions which contact the first and second gate dielectric layers 17A and 17B.

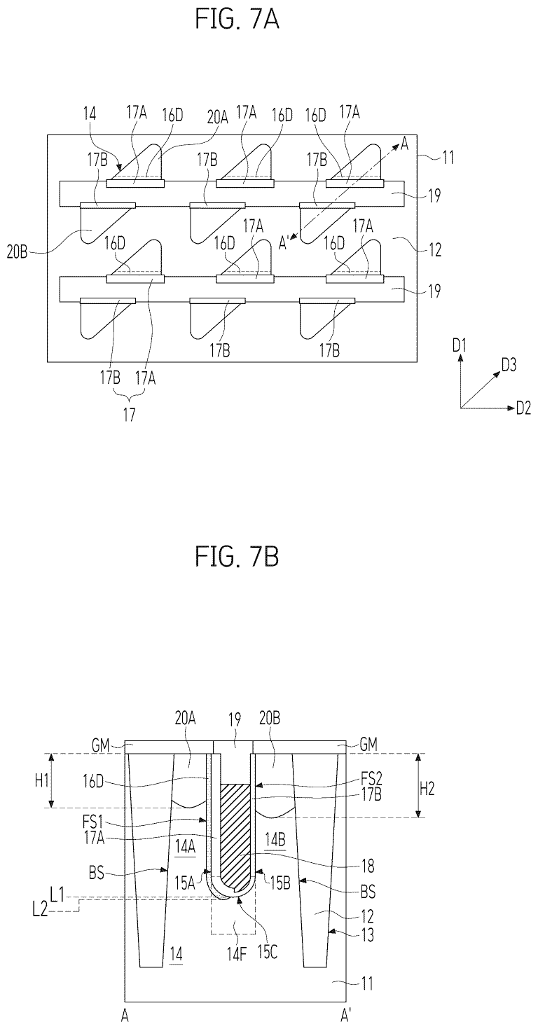

Referring to FIGS. 7A and 7B, a capping layer 19 may be formed over the gate electrode 18 and may cover the exposed top surface of the gate electrode. The capping layer 19 may serve to protect the gate electrode 18. The capping layer 19 may fill the upper portion of the gate trench 15 over the gate electrode 18. The top surface of the capping layer 19 may be disposed at the same level as the top surface of the hard mask layer GM. The capping layer 19 may include, for example, silicon oxide, silicon nitride, or a combination thereof. According to an embodiment of the present disclosure, the capping layer 19 may include fluorine-containing silicon oxide, fluorine-containing silicon nitride, or a combination thereof. Fluorine-containing silicon nitride refers to a silicon nitride layer that is doped with fluorine.

After forming the capping layer 19, a first doped region 20A and a second doped region 20B may be formed in the first nodes 14A and the second nodes 14B, respectively. The first doped region 20A and the second doped region 20B may be formed by performing a doping process with conductive dopants. The first doped regions 20A may be formed in the first nodes 14A, and the second doped regions 20B may be formed in the second nodes 14B. The first and second doped regions 20A and 20B may be referred to as source/drain regions.

The first doped region 20A and the second doped region 20B may be regions doped with a conductive dopant. For example, the conductive dopant may include phosphorus (P), arsenic (As), antimony (Sb), or boron (B). The first doped region 20A and the second doped region 20B may be doped with a dopant of the same conductivity type. The first doped region 20A and the second doped region 20B may be disposed in the active regions 14 on both sides of the gate trench 15. The bottom surfaces of the first doped region 20A and the second doped region 20B may be disposed at a predetermined depth from the top surfaces of the active regions 14. The first doped region 20A may contact the growth promotion region 16D. The depth H1 of the first doped region 20A may be smaller than the depth H2 of the second doped region 20B. The depth H1 of the first doped region 20A may be smaller than the depth of the growth promotion region 16D. The bottom surfaces of the first doped region 20A and the second doped region 20B may be higher than the bottom surface 15C of the gate trench 15. The first doped region 20A may be referred to as a ‘first source/drain region’, and the second doped region 20B may be referred to as a ‘second source/drain region.’ A channel may be defined between the first doped region 20A and the second doped region 20B by the gate electrode 18. The channel may be defined along the profile of the gate trench 15.

Subsequently, a first contact node 141, a bit line 140, a second contact node 151 and a data storage element 150 as illustrated in FIGS. 1A and 1B may be formed sequentially. For example, forming the first contact node 141 and the bit line 140 coupled to the second doped region 20B and forming the second contact node 151 and the data storage element 150 coupled to the first doped region 20A may be performed.

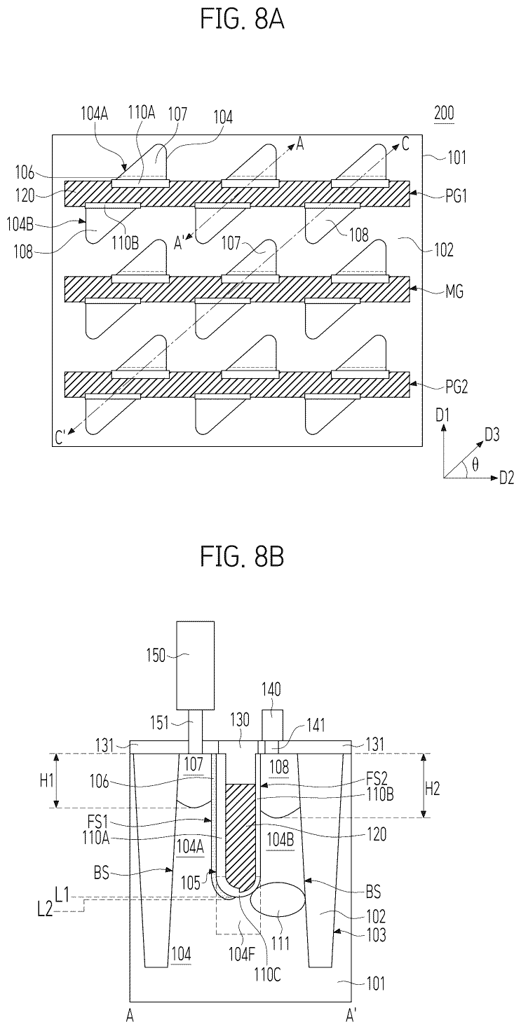

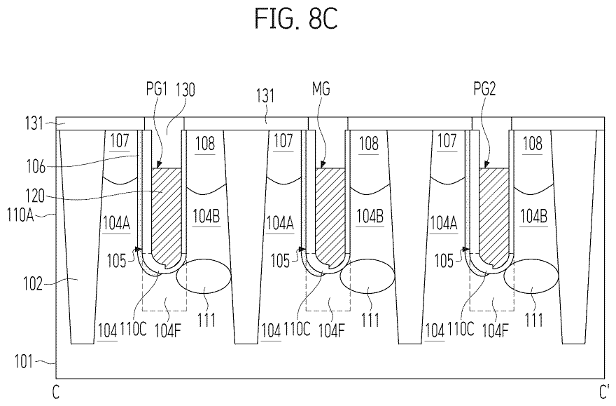

FIG. 8A is a plan view illustrating a semiconductor device in accordance with an embodiment of the present disclosure. FIG. 8B is a cross-sectional view taken along a line A-A′ shown in FIG. 8A, and FIG. 8C is a cross-sectional view taken along a line C-C′ shown in FIG. 8A. The semiconductor device 200 of FIGS. 8A to 8C may be similar to the semiconductor device 100 of FIG. 1B. Hereinafter, detailed description on the constituent elements also appearing in FIG. 1B will be omitted.

Referring to FIGS. 8A to 8C, the semiconductor device 200 may include a substrate 101, an isolation layer 102, active regions 104 including a first node 104A and a second node 104B that are isolated from each other by a gate trench 105, a first gate dielectric layer 110A formed on a flat sidewall FS1 of the first node 104A, a second gate dielectric layer 110B formed on a flat sidewall FS2 of the second node 104B, a third gate dielectric layer 110C formed on the bottom surface of the gate trench 105, a gate electrode 120 partially filling the gate trench 105 over the first to third gate dielectric layers 110A, 110B, and 110C, a capping layer 130 over the gate electrode 120, a first doped region 107 formed in the first node 104A, a second doped region 108 formed in the second node 104B, a first contact node 141 and a bit line 140 coupled to the second doped region 108, a second contact node 151 and a data storage element 150 coupled to the first doped region 107, and a growth promotion region 106 between the first gate dielectric layer 110A and the first doped region 107. The bit lines 140 may extend in the first direction D1, and the gate electrodes 120 may extend in the second direction D2. The first direction D1 and the second direction D2 may be orthogonal to each other. The active regions 104 may be arranged in a unidirection of the third direction D3.

In the semiconductor device 200, one gate electrode 120 may be formed in one active region 104. The semiconductor device 200 may include a memory cell of a 1G1A structure.

The semiconductor device 200 may further include a highly doped region 111. The highly doped region 111 may be formed in the second node 104B. The highly doped region 111 may be vertically spaced apart from the second doped region 108. The highly doped region 111 may be adjacent to the third gate dielectric layer 110C. The highly doped region 111 may include a dopant that is different from those of the first and second doped regions 107 and 108. The highly doped region 111 may contain a P-type dopant, such as boron, and the first and second doped regions 107 and 108 may contain an N-type dopant. The highly doped region 111 may contact the fin region 104F, the isolation layer 102, and the third gate dielectric layer 110C.

As described above, a single doped region of the first doped region 107 may be formed in the first node 104A, and a double doped region of the second doped region 108 and the highly doped region 111 may be disposed in the second node 104B. After the above operations are completed, the semiconductor device 200 including a memory cell of a 1G1A structure may include a doped region of an asymmetric structure.

The highly doped region 111 may serve to increase the potential barrier. Accordingly, the row hammer that may be caused by passing gates PG1 and PG2 during an operation of a main gate MG may be improved.

Row hammer refers to a phenomenon in which data stored in a capacitor operated by the main gate MG are distorted when the passing gates PG1 and PG2 disposed adjacent to the main gate MG operate continuously. When the passing gates PG1 and PG2 are turned on, the electrons stored in a capacitor disposed adjacent to the main gate MG may migrate to be trapped in the interface between the active region 104 adjacent to the passing gates PG1 and PG2 and the isolation layer 102. When the passing gates PG1 and PG2 are turned off, some of the discharged electrons may be recombined with holes or electrons that cross over the potential barrier of the main gate MG may distort the data. The row hammer may cause Gate-Induced Drain Leakage (GIDL) to decrease the reliability of semiconductor devices.

The highly doped region 111 in accordance with this embodiment of the present disclosure may serve to increase the potential barrier. Accordingly, the row hammer may be improved, and off-leakage and refresh time Tref may be improved. The refresh time Tref refers to a time interval that is taken to receive refresh commands.

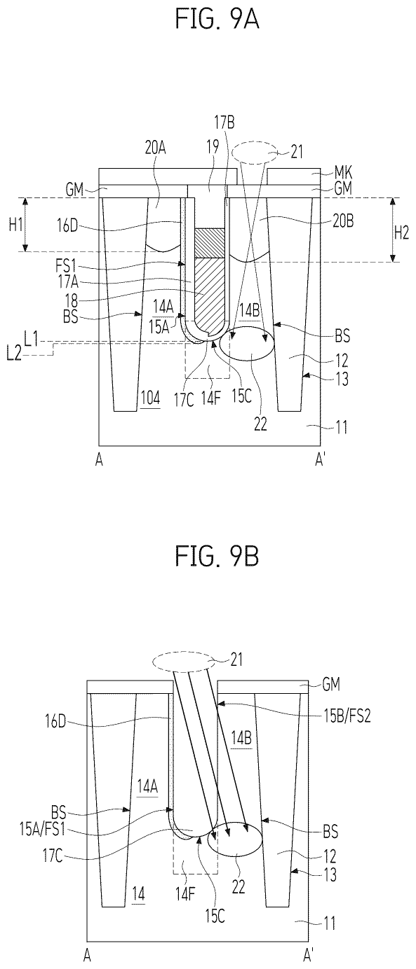

FIG. 9A illustrates a method for forming the highly doped region 111 shown in FIG. 8B. The method for fabricating the semiconductor device 200 illustrated in FIGS. 8A to 8C may be similar to what is illustrated in FIGS. 3A to 7B.

A series of the operations illustrated in FIGS. 3A to 7B may be performed.

After the first and second doped regions 20A and 20B are formed subsequent to FIGS. 7A and 7B, as illustrated in FIG. 9A, a mask layer MK that selectively only opens the second node 14B among the first node 14A and the second node 14B may be formed.

A high doping process 21 of a dopant may be performed using the mask layer MK as a barrier. The high doping process 21 may include a doping process of P-type dopants. For example, the high doping process 21 may include a boron implantation process. The high doping process 21 may use a rotation method. As used herein, “high doping” means a high concentration of a dopant such that there is significant interaction between the dopant atoms. For example, a dopant concentration of the high doping process 21 may range from approximately 1.0×10¹² atoms/cm³ to approximately 1.0×10¹⁶ atoms/cm³.

A highly doped region 22 may be formed in the second node 14B through the high doping process 21.

FIG. 9B is another embodiment of a method for forming the highly doped region 111 shown in FIG. 8B.

A series of operations as illustrated in FIGS. 3A to 4B may be performed.

After the growth promotion region 16D is formed subsequent to FIGS. 4A and 4B, the high doping process 21 of a dopant may be performed using hard mask layer GM as a barrier, as illustrated in FIG. 9B. The high doping process 21 may include a doping process of P-type dopants. For example, the high doping process 21 may include a boron implantation process. The high doping process 21 may use a tilt implantation method.

A highly doped region 22 may be formed in the second node 14B through the high doping process 21.

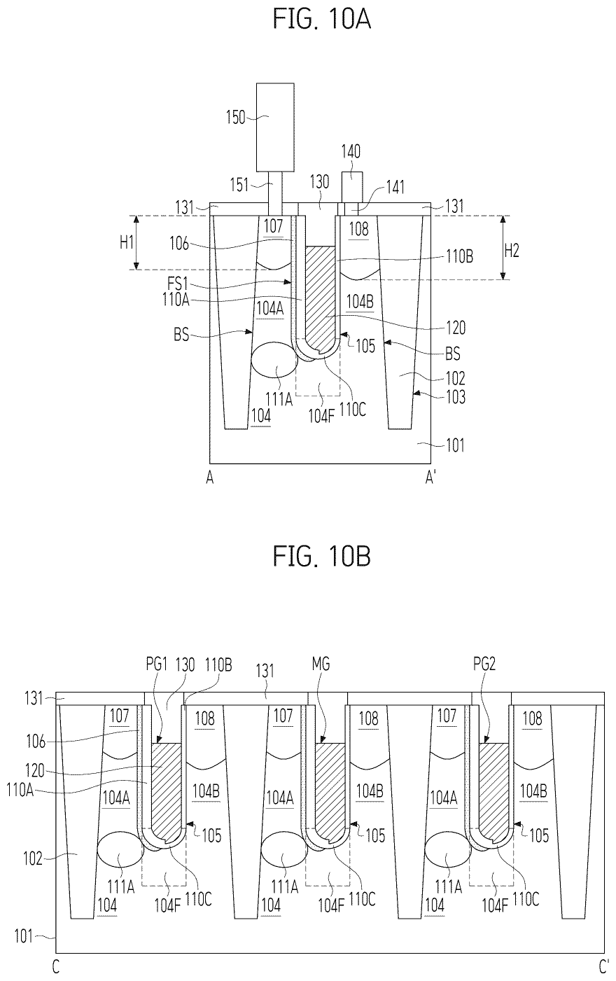

FIGS. 10A and 10B are cross-sectional views taken along lines A-A′ and C-C′ shown in FIG. 8A, respectively. The semiconductor device of FIGS. 10A and 10B is similar to the semiconductor device 100 of FIGS. 8B and 8C. Hereinafter, detailed description on the constituent elements also appearing in FIGS. 8B and 8C may be omitted.

Referring to FIGS. 10A and 10B, a highly doped region 111A may be formed in the first node 104A proximate to the third gate dielectric layer 110C. The highly doped region 111A may overlap with the first doped region 107. The highly doped region 111A may be vertically spaced apart from the first doped region 107. The highly doped region 111A may be adjacent to the third gate dielectric layer 110C. The highly doped region 111A may include a dopant that is different from those of the first and second doped regions 107 and 108. The highly doped region 111A may contain a P-type dopant, such as boron, and the first and second doped regions 107 and 108 may contain an N-type dopant. The highly doped region 111A may contact the fin region 104F, the isolation layer 102, and the growth promotion region 106.

As described above, a single doped region of the second doped region 108 may be formed in the second node 104B, and a double doped region of the first doped region 107 and the highly doped region 111A may be disposed in the first node 104A. After all, the semiconductor device may include a doped region of an asymmetric structure.

The highly doped region 111A may serve to increase the potential barrier. Accordingly, the row hammer caused by the passing gates PG1 and PG2 during an operation of the main gate MG may be improved.

The highly doped region 111A may be referred to as a potential barrier region. The highly doped region 111A may contact the isolation layers 102 and the fin region 104F.

For forming the highly doped region 111A, as illustrated in FIG. 9A, after the first and second doped regions 20A and 20B are formed, a high doping process 21 of a dopant may be performed using the mask layer MK as a barrier. Also, in order to form the highly doped region 111A, as illustrated in FIG. 9B, after the growth promotion region 16D is formed, a high doping process of a dopant may be performed using the hard mask layer GM as a barrier.

Referring to FIGS. 8A to 10B, highly doped regions 111 and 111A may be formed in the first node 104A and the second node 104B, respectively. Accordingly, a doped region of an asymmetric structure may be formed.

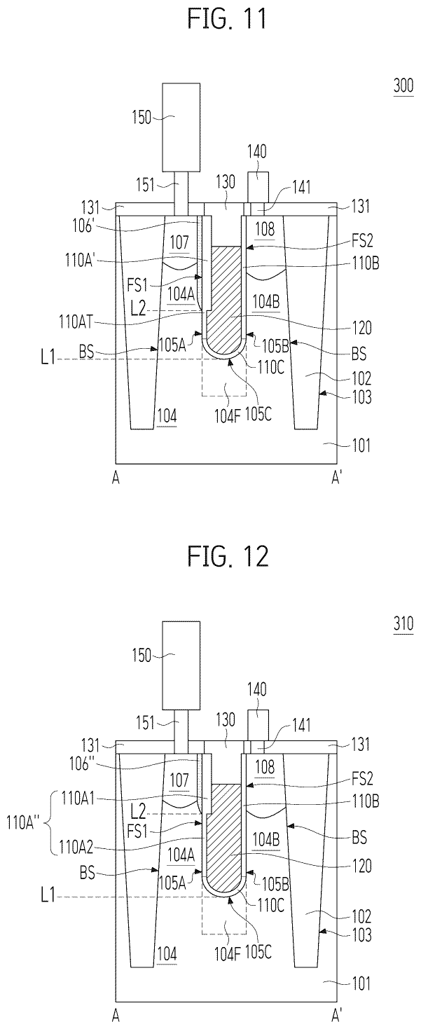

FIG. 11 is a cross-sectional view illustrating a semiconductor device in accordance with an embodiment of the present disclosure. The semiconductor device 300 shown in FIG. 11 may be similar to the semiconductor device 100 shown in FIG. 1B. Hereinafter, detailed description on the constituent elements also appearing in FIG. 1B may be omitted.

The semiconductor device 300 may include a substrate 101, an isolation layer 102, an active region 104 including a first node 104A and a second node 104B that are isolated from each other by a gate trench 105, a first gate dielectric layer 110A′ formed on the flat sidewall FS1 of the first node 104A, a second gate dielectric layer 110B formed on the flat sidewall FS2 of the second node 104B, a third gate dielectric layer 110C formed on the bottom surface of the gate trench 105, a gate electrode 120 partially filling the gate trench 105 over the first to third gate dielectric layers 110A′, 110B, and 110C, a capping layer 130 over the gate electrode 120, a first doped region 107 formed in the first node 104A, a second doped region 108 formed in the second node 104B, a first contact node 141 and a bit line 140 coupled to the second doped region 108, a second contact node 151 and a data storage element 150 coupled to the first doped region 107, and a growth promotion region 106′ between the first gate dielectric layer 110A′ and the first doped region 107. According to an embodiment of the present disclosure, the semiconductor device 300 may further include the highly doped region 111 shown in FIG. 8B.

The semiconductor device 300 may include a memory cell of a 1G1A structure.

Referring to FIG. 11, the thickness of the first gate dielectric layer 110A′ may be thicker than the thickness of the second gate dielectric layer 110B. The bottom surface 105C of the gate trench 105 may be disposed at a first level L1, and the bottom surface of the growth promotion region 106′ may be disposed at a second level L2. The second level L2 may be shallower than the first level L1. The first gate dielectric layer 110A′ may include a thin portion 110AT, and the thin portion 110AT may be disposed between the first level L1 and the second level L2.

The growth promotion region 106′ shown in FIG. 11 may have a smaller vertical height than the growth promotion region 106 shown in FIG. 1B.

FIG. 12 is a cross-sectional view illustrating a semiconductor device in accordance with an embodiment of the present disclosure. The semiconductor device 310 shown in FIG. 12 may be similar to the semiconductor device 100 shown in FIG. 1B and the semiconductor device 300 shown in FIG. 11. Hereinafter, detailed description on the constituent elements also appearing in FIGS. 1B and 11 may be omitted.

The semiconductor device 310 may include a substrate 101, an isolation layer 102, an active region 104 including a first node 104A and a second node 104B that are isolated from each other by a gate trench 105, a first gate dielectric layer 110A″ formed on the flat sidewall FS1 of the first node 104A, a second gate dielectric layer 110B formed on the flat sidewall FS2 of the second node 104B, a third gate dielectric layer 110C formed on the bottom surface of the gate trench 105, a gate electrode 120 partially filling the gate trench 105 over the first to third gate dielectric layers 110A″, 110B, and 110C, a capping layer 130 over the gate electrode 120, a first doped region 107 formed in the first node 104A, a second doped region 108 formed in the second node 104B, a first contact node 141 and a bit line 140 coupled to the second doped region 108, a second contact node 151 and a data storage element 150 coupled to the first doped region 107, a growth promotion region 106″ between the first gate dielectric layer 110″ and the first doped region 107. According to an embodiment of the present disclosure, the semiconductor device 310 may further include the highly doped region 111 shown in FIG. 8B.

The semiconductor device 310 may include a memory cell of a 1G1A structure.

The first gate dielectric layer 110A″ may include a first portion 110A1 and a second portion 110A2, and the first portion 110A1 may be thicker than the second portion 110A2. The growth promotion region 106″ may be disposed between the first portion 110A1 of the first gate dielectric layer 110A″ and the first doped region 107. The second portion 110A2 of the first gate dielectric layer 110A″ may not contact the growth promotion region 106″.

Referring to FIG. 12, the thickness of the first portion 110A1 of the first gate dielectric layer 110A″ may be thicker than the thickness of the second gate dielectric layer 110B. The bottom surface 105C of the gate trench 105 may be disposed at a first level L1, and the bottom surface of the growth promotion region 106″ may be disposed at a second level L2. The bottom surface of the first doped region 107 and the bottom surface of the growth promotion region 106″ may be disposed at the second level L2. The second level L2 may be shallower than the first level L1. The second portion 110A2 of the first gate dielectric layer 110A″ may be disposed between the first level L1 and the second level L2.

The growth promotion region 106″ shown in FIG. 12 may have a smaller vertical height than the growth promotion region 106 shown in FIG. 1B and the growth promotion region 106′ shown in FIG. 11.

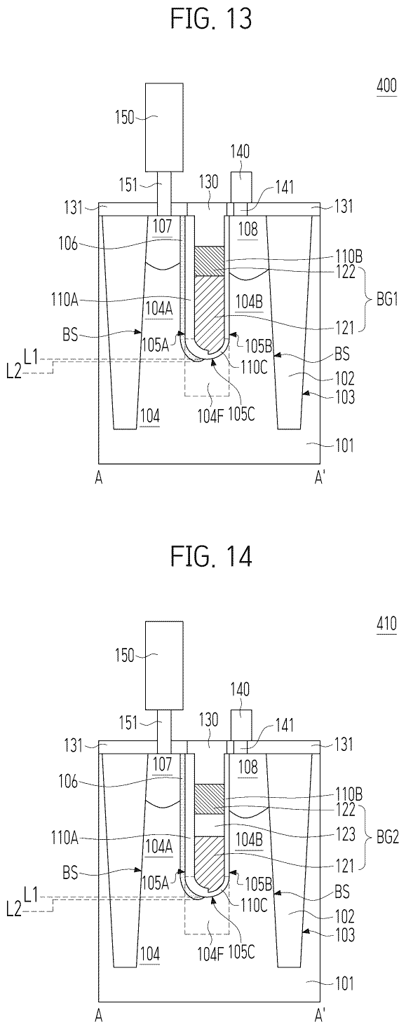

FIG. 13 is a cross-sectional view illustrating a semiconductor device in accordance with an embodiment of the present disclosure. The semiconductor device 400 shown in FIG. 13 may be similar to the semiconductor device 100 shown in FIG. 1B. Hereinafter, detailed description on the constituent elements also appearing in FIG. 1B may be omitted.

The semiconductor device 400 may include a substrate 101, an isolation layer 102, an active region 104 including a first node 104A and a second node 104B that are isolated from each other by a gate trench 105, a first gate dielectric layer 110A formed on the flat sidewall FS1 of the first node 104A, a second gate dielectric layer 110B formed on the flat sidewall FS2 of the second node 104B, a third gate dielectric layer 110C formed on the bottom surface of the gate trench 105, a buried gate electrode BG1 partially filling the gate trench 105 over the first to third gate dielectric layers 110A, 110B, and 110C, a capping layer 130 over the buried gate electrode BG1, a first doped region 107 formed in the first node 104A, a second doped region 108 formed in the second node 104B, a second contact node 141 and a bit line 140 coupled to the second doped region 108, a second contact node 151 and a data storage element 150 coupled to the first doped region 107, and a growth promotion region 106 between the first gate dielectric layer 110A and the first doped region 107. According to an embodiment of the present disclosure, the semiconductor device 400 may further include the highly doped region 111 shown in FIG. 8B. The first gate dielectric layer 110A may be thicker than the second gate dielectric layer 110B. A growth promotion region 106 may be disposed between the first gate dielectric layer 110A and the first doped region 107.

The semiconductor device 400 may include a memory cell of a 1G1A structure.

The buried gate electrode BG1 of the semiconductor device 400 shown in FIG. 13 may have a dual work function structure. The buried gate electrode BG1 may include a lower gate electrode 121 and an upper gate electrode 122. The lower gate electrode 121 may include a high work function material, and the upper gate electrode 122 may include a low work function material. The lower gate electrode 121 may include a metal-based material, and the upper gate electrode 122 may include a semiconductor material. The lower gate electrode 121 may be titanium nitride, tungsten, or a stack thereof, and the upper gate electrode 122 may be doped polysilicon. The doped polysilicon may refer to polysilicon doped with an N-type dopant. According to an embodiment of the present disclosure, the lower gate electrode 121 may be high work function titanium nitride, and the upper gate electrode 122 may include a low work function titanium nitride. The difference between the work function of the high work function titanium nitride and the work function of the low work function titanium nitride may be adjusted according to the content of nitrogen. Nitrogen-rich titanium nitride (nitrogen-rich TiN) whose nitrogen content is higher than stoichiometric titanium nitride may have a high work function.

The upper gate electrode 122 may horizontally overlap with the growth promotion region 106, the first doped region 107, and the second doped region 108.

The GIDL may be further improved by the upper gate electrode 122 of a low work function.

FIG. 14 is a cross-sectional view illustrating a semiconductor device in accordance with an embodiment of the present disclosure. The semiconductor device 410 of FIG. 14 may be similar to the semiconductor device 100 shown in FIG. 1B and the semiconductor device 400 shown in FIG. 13. Hereinafter, detailed description on the constituent elements also appearing in FIGS. 1B and 13 may be omitted.

The semiconductor device 410 may include a substrate 101, an isolation layer 102, an active region 104 including a first node 104A and a second node 104B that are isolated from each other by a gate trench 105, a first gate dielectric layer 110A formed on the flat sidewall FS1 of the first node 104A, a second gate dielectric layer 110B formed on the flat sidewall FS2 of the second node 104B, a third gate dielectric layer 110C formed on the bottom surface of the gate trench 105, a buried gate electrode BG2 partially filling the gate trench 105 over the first to third gate dielectric layers 110A, 110B, and 110C, a capping layer 130 over the buried gate electrode BG2, a first doped region 107 formed in the first node 104A, a second doped region 108 formed in the second node 104B, a first contact node 141 and a bit line 140 coupled to the second doped region 108, a second contact node 151 and a data storage element 150 coupled to the first doped region 107, and a growth promotion region 106 between the first gate dielectric layer 110A and the first doped region 107. According to an embodiment of the present disclosure, the semiconductor device 400 may further include a highly doped region 111 shown in FIG. 8B. The first gate dielectric layer 110A may be thicker than the second gate dielectric layer 110B. The growth promotion region 106 may be disposed between the first gate dielectric layer 110A and the first doped region 107. The semiconductor device 410 may include a memory cell of a 1G1A structure.

The buried gate electrode BG2 of the semiconductor device 410 shown in FIG. 14 may have a triple work function structure. The buried gate electrode BG2 may include a lower gate electrode 121, an upper gate electrode 122, and a middle gate electrode 123 disposed between the lower gate electrode 121 and the upper gate electrode 122. The lower gate electrode 121 may include a high work function material, and the upper gate electrode 122 may include a low work function material, and the middle gate electrode 123 may include a middle work function material. The middle work function of the middle gate electrode 123 may be greater than the low work function of the upper gate electrode 122 and smaller than the high work function of the lower gate electrode 121. The lower gate electrode 121 may include a metal-based material, and the upper gate electrode 122 may include a semiconductor material. The lower gate electrode 121 may include titanium nitride, tungsten, or a stack thereof, and the upper gate electrode 122 may include doped polysilicon. Doped polysilicon may refer to polysilicon that is doped with an N-type dopant'. According to an embodiment of the present disclosure, the lower gate electrode 121 may include a high work function titanium nitride, and the upper gate electrode 122 may include a low work function titanium nitride. The difference between the work function of the high work function titanium nitride and the work function of the low work function titanium nitride may be adjusted according to the content of nitrogen. Nitrogen-rich titanium nitride (nitrogen-rich TiN) whose nitrogen content is higher than stoichiometric titanium nitride may have a high work function. The upper gate electrode 122 may horizontally overlap with the growth promotion region 106, the first doped region 107, and the second doped region 108.

The GIDL may be further improved by the upper gate electrode 122 of a low work function.

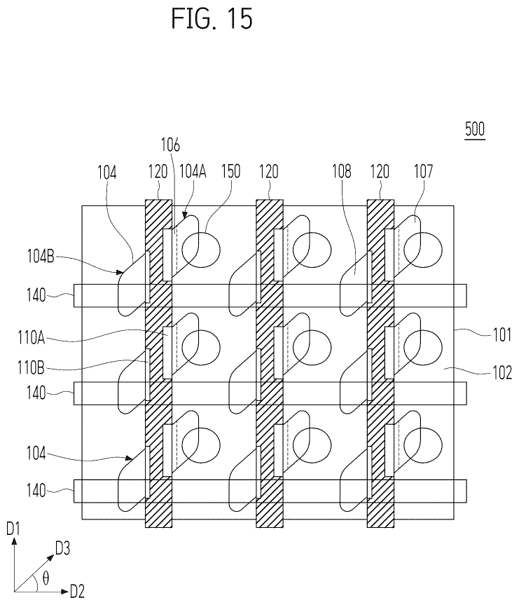

FIG. 15 is a plan view illustrating a semiconductor device in accordance with an embodiment of the present disclosure. The semiconductor device 500 shown in FIG. 15 may be similar to the semiconductor device 100 shown in FIG. 1A. Hereinafter, detailed description on the constituent elements also appearing in FIG. 1A may be omitted.

Referring to FIGS. 1A and 15, the semiconductor device 500 may include a substrate 101, an isolation layer 102, an active region 104 including a first node 104A and a second node 104B that are isolated from each other by a gate trench 105, a first gate dielectric layer 110A formed on the flat sidewall of the first node 104A, a second gate dielectric layer 110B formed on the flat sidewall of the second node 104B, a gate electrode 120 partially filling the gate trench 105 over the first and second gate dielectric layers 110A and 110B, a capping layer 130 over the gate electrode 120, a first doped region 107 formed in the first node 104A, a second doped region 108 formed in the second node 104B, a first contact node 141 and a bit line 140 coupled to the second doped region 108, a second contact node 151 and a data storage element 150 coupled to the first doped region 107, and a growth promotion region 106 between the first gate dielectric layer 110A and the first doped region 107. According to an embodiment of the present disclosure, the semiconductor device 310 may further include the highly doped region 111 shown in FIG. 8B.

In the semiconductor device 500, the gate electrode 120 may extend in the first direction D1, and the bit line 140 may extend in the second direction D2. The gate trench 105 in which the gate electrode 120 is formed may divide one active region 104 into a first node 104A and a second node 104B.

The semiconductor device 500 may include a memory cell of a 1G1A structure.

According to the embodiment of the present disclosure, it is possible to improve leakage and refresh by forming the thickness of the gate dielectric layer of the buried gate structure asymmetrically.

Also, according to the embodiment of the present disclosure, it is possible to improve the row hammer and a refresh operation by forming the doped regions of an asymmetric structure.

While the embodiments of the present disclosure have been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device comprising:
a plurality of active regions in a substrate;
a gate trench formed in at least one of the plurality of the active regions, the gate trench including a first sidewall, a second sidewall opposite to the first sidewall, and a bottom sidewall;
a growth promotion region formed on the first sidewall of the trench;
a first gate dielectric layer formed on the first sidewall of the trench to contact the growth promotion region;
a second gate dielectric layer formed on the second sidewall of the trench to be thinner than the first gate dielectric layer; and
a gate electrode partially filling the trench over the first and second gate dielectric layers.

2. The semiconductor device of claim 1, wherein the growth promotion region includes a growth promotion species for increasing a growth rate of the first gate dielectric layer.

3. The semiconductor device of claim 1, wherein the growth promotion region includes oxygen, fluorine, or a combination thereof.

4. The semiconductor device of claim 1, wherein the first gate dielectric layer includes silicon oxide, and the growth promotion region includes an oxygen-containing silicon layer.

5. The semiconductor device of claim 1, wherein the first gate dielectric layer includes silicon oxide, and the growth promotion region includes a fluorine-containing silicon layer.

6. The semiconductor device of claim 1, wherein the first gate dielectric layer includes silicon oxide, and the growth promotion region includes a silicon layer containing oxygen and fluorine.

7. The semiconductor device of claim 1, wherein the first gate dielectric layer includes silicon oxide, and
the growth promotion region includes silicon oxide or fluorine-containing silicon oxide.

8. The semiconductor device of claim 1, wherein one gate electrode is disposed in each active region of the active regions.

9. The semiconductor device of claim 1, wherein the active region includes a first node and a second node obtained by being divided by the trench.

10. The semiconductor device of claim 9, further comprising:
a first doped region formed in the first node;
a second doped region formed in the second node to be deeper than the first doped region;
a data storage element coupled to the first doped region; and
a bit line coupled to the second doped region.

11. A semiconductor device comprising:
a substrate;
an isolation layer defining an active region including a first node and a second node in the substrate;
a gate trench formed between the first node and the second node and including a first sidewall and a second sidewall;
a growth promotion region formed on the first sidewall of the trench;
a first gate dielectric layer formed on the first sidewall of the trench to contact the growth promotion region;
a second gate dielectric layer formed on the second sidewall of the trench to be thinner than the first gate dielectric layer;
a gate electrode partially filling the trench over the first and second gate dielectric layers; and
a potential barrier region formed in the second node below the second sidewall of the gate trench.

12. The semiconductor device of claim 11, further comprising:
a first doped region formed in the first node; and
a second doped region formed in the second node to be deeper than the first doped region,
wherein the potential barrier region is disposed below the second doped region.

13. The semiconductor device of claim 12, wherein the potential barrier region includes a P-type dopant, and
the first and second doped regions include an N-type dopant.

14. The semiconductor device of claim 11, wherein the growth promotion region includes a growth promotion species to increase a growth rate of the first gate dielectric layer.

15. The semiconductor device of claim 11, wherein the growth promotion region includes oxygen, fluorine, or a combination thereof.

16. The semiconductor device of claim 11, wherein the first gate dielectric layer includes silicon oxide, and
the growth promotion region includes an oxygen-containing silicon layer, a fluorine-containing silicon layer, or a silicon layer containing oxygen and fluorine.

17. The semiconductor device of claim 11, wherein the first gate dielectric layer includes silicon oxide, and
the growth promotion region includes silicon oxide or fluorine-containing silicon oxide.

18. The semiconductor device of claim 11, further comprising:
a data storage element coupled to the first doped region; and
a bit line coupled to the second doped region.

19. The semiconductor device of claim 11, wherein one gate electrode is disposed in each active region of the active regions.
